(19) United States
(12) Patent Application Publication
(10) Pub. No.: US 2006/0194155 A1
(43) Pub. Date: Aug. 31, 2006

(54) Resist pattern forming method and semiconductor device manufacturing method

(76) Inventors: Daisuke Kawamura, Yokohama-shi (JP); Tsuyoshi Shibata, Kikuchi-gun (JP); Shinichi Ito, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/360,502

(22) Filed: Feb. 24, 2006

(30) Foreign Application Priority Data
Feb. 24, 2005 (JP) 2005-049394

(51) Int. Cl. G03F 7/00

(52) U.S. Cl. 430/394

(57) ABSTRACT

A resist pattern forming method includes forming a resist film above a substrate. A first exposure is performed in which a specific region of an edge of the resist film is irradiated with light much enough to allow subsequent development to dissolve the resist film, thereby forming a latent image in the resist film at the edge. The resist film whose edge has been irradiated is rinsed. A second exposure is performed in which a desired pattern of light is projected onto an exposure region of the rinsed resist film via a projection optical system of an immersion exposure tool with liquid whose refractive index is larger than that of air existing between the exposure region and the substrate-side face of a component element closest to the substrate in the projection optical system. Development on the exposure region of the resist film is performed.

### CROSS-REFERENCE TO RELATED APPLICATIONS

This application is based upon and claims the benefit of priority from prior Japanese Patent Application No. 2005-049394, filed Feb. 24, 2005, the entire contents of which are incorporated herein by reference.

### BACKGROUND OF THE INVENTION

1. Field of the Invention

This invention relates to a resist pattern forming method and a semiconductor device manufacturing method, and more particularly to a resist pattern forming method using liquid immersion exposure.

2. Description of the Related Art

In the semiconductor manufacturing processes, it is desirable that the resist film formed on the substrate should be removed at the substrate bevel part and the peripheral part (hereinafter, referred to as the substrate edge) and that the thickness of the resist film should decrease sharply at the removed part. Since a to-be-processed film in a lower layer is processed with the resist film as an etching mask, if a resist film with a half-finished thickness remains before the processing, it leads to-be-processed film with a half-finished thickness. Such a shape leads to dust and/or contamination in the next process steps. Moreover, the irregularity of the edge of the substrate causes abnormal coating or removing of a coated film, leading to pattern defects such as resist pattern defects after development.

Therefore, in a conventional exposure tool (hereinafter, a dry exposure tool) where the optical path between the last element at the downstream side in the optical path of the projection optical system in the exposure tool and the substrate on which a stacked film including a resist film are formed is filled with air or a gas whose refractive index is almost 1, such as nitrogen, a wafer edge exposure step is provided. The removal of the solution by spin-coating resist solution (hereinafter, referred to as edge rinse) is carried out in the spin-coating process. In addition, the wafer edge exposure step is carried out between a resist coating film heating step (hereinafter, PAB: Post Applied Bake) and a pattern exposure step. In the wafer edge exposure step, the edge of the resist film is irradiated with light strong enough to cause the resist film to dissolve at the edge in a subsequent development. Conducting the wafer edge exposure enables the resist film at the peripheral part of the substrate to be formed into a sharp shape.

In contrast with dry exposure, so-called liquid immersion exposure is known. With liquid immersion exposure, the design of a suitable optical system makes it possible to form a more microscopic pattern than with dry exposure.

However, it is known that low-molecular components in the film are eluted from the resist film into the immersion fluid in liquid immersion exposure (W. Hinsberg, et al., “Proc. SPIE,” vol. 5376, 2004, pp. 21-33; J. Taylor, et al., “Proc. SPIE,” vol. 5376, 2004, pp. 34-43; and S. Kishimura, “Proc. SPIE,” vol. 5376, 2004, pp. 44-55). Photo acid generator (PAG), its photoreactive product or photogenerated acid, a base acting as an acid quencher, the resist solvent existing as the remaining solvent in the resist film, and the like have been reported as eluted low-molecular components in academic conferences or the like. Photogenerated acid is especially eluted much.

When these low-molecular components are eluted into the immersion fluid, the followings are concerned: 1. a change in the refractive index of the immersion fluid gives rise to a difference of optical length, 2. the occurrence of air bubbles causes a difference of optical length and flare, 3. flare and a difference of optical length occur due to the projection optical system clouds as a result of the deposition of or corrosion by eluted material, and 4. the immersion fluid retaining function deteriorates due to the contamination of the wafer stage or shower head for supplying the immersion fluid only to the periphery of the optical path. Problems 1 and 2 may lead to a fluctuation in the dimensions due to local aberration or focus fluctuation, problem 3 may lead to the abnormal dimensions of the resist film due to the deterioration of the optical image chiefly as a result of long-term use of the tool, and problem 4 may result in pattern defects and pattern contamination due to the formation of watermarks on the substrate and/or wafer stage.

### BRIEF SUMMARY OF THE INVENTION

According to a first aspect of the present invention, there is provided a resist pattern forming method comprising: forming a resist film above a substrate; performing a first exposure in which a specific region of an edge of the resist film is irradiated with light much enough to allow subsequent development to dissolve the resist film, thereby forming a latent image in the resist film at the edge; rinsing the resist film whose edge has been irradiated; performing a second exposure in which a desired pattern of light is projected onto an exposure region of the rinsed resist film via a projection optical system of an immersion exposure tool whose refractive index is larger than that of air existing between the exposure region and the substrate-side face of a component element closest to the substrate in the projection optical system; and performing development on the exposure region of the resist film.

According to a second aspect of the present invention, there is provided a resist pattern forming method comprising: forming a resist film above a substrate; performing a first exposure in which a desired pattern of light is projected onto a exposure region of the resist film via a projection optical system of an immersion exposure tool with liquid whose refractive index is larger than that of air existing between the exposure region and the substrate-side face of a component element closest to the substrate in the projection optical system; after the first exposure, performing a second exposure in which a specific region of an edge of the resist film is irradiated with light much enough to allow subsequent development to dissolve the resist film, thereby forming a latent image in the resist film at the edge; and performing development on the exposure region of the resist film.

### BRIEF DESCRIPTION OF THE SEVERAL VIEWS OF THE DRAWING

FIG. 1 is a flowchart of a conventional resist pattern forming method using a dry exposure tool;

FIGS. 2 and 3 are flowcharts of a resist pattern forming method expected when liquid immersion exposure and wafer edge exposure are carried out;

FIG. 4 is a flowchart of a resist pattern forming method according to a first embodiment of the present invention;

FIGS. 5, 6, and 7 show part of the resist pattern forming steps;

FIGS. 8 and 9 are diagrams of a wafer edge exposure region;

FIGS. 10 and 11 show part of the resist pattern forming steps;

FIG. 12 is a flowchart of a resist pattern forming method according to a second embodiment of the present invention;

FIG. 13 shows part of the resist pattern forming steps;

FIG. 14 is a flowchart of a resist pattern forming method according to a third embodiment of the present invention;

FIG. 15 is a flowchart of a resist pattern forming method according to a fourth embodiment of the present invention; and

FIG. 16 is a flowchart of a resist pattern forming method according to a fifth embodiment of the present invention.

### DETAILED DESCRIPTION OF THE INVENTION

The inventors of this invention have studied how to form a resist pattern excellent in pattern dimensional accuracy in the course of carrying out developments related to the invention. As a result, the inventors have obtained the findings described below.

### REFERENCE EXAMPLE 1

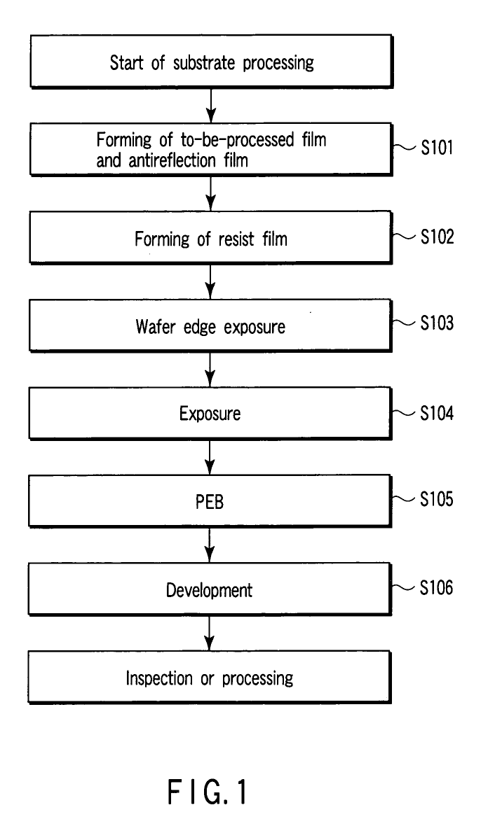

First, referring to FIG. 1, lithograph using a dry exposure tool will be explained.

[Step S101]

On a substrate, a to-be-processed film and single layer or more than one layers of antireflection film are formed in sequence. Then, on the antireflection film, dispensed resist solution is spread by spin-coating, thereby forming a resist coating film.

[Step S102]

The substrate on which the resist coating film is formed is heated, thereby forming a resist film.

[Step S103]

Wafer edge exposure is carried out to a specific range of the edge of the substrate on which the resist film has been formed. When a commercially available coating and development tool and a commercially available exposure tool are used, wafer edge exposure is normally incorporated in the interface unit that transfers a wafer from the coating and development tool to the exposure tool. Therefore, the wafer edge exposure is usually carried out immediately before the exposure.

[Step S104]

The substrate having gone through wafer edge exposure is subjected to pattern exposure via a specific photomask using the dry exposure tool, thereby causing photoreaction in the position according to the pattern exposure of the resist film.

[Step S105]

The substrate having gone through pattern exposure is subjected to a specific heating process after pattern exposure (PEB: Post Exposure Bake). As a result, chemical reactions take place at the site where photoreaction occurred in the resist film and its surroundings, thereby changing the solubility to a specific developer for the resist.

[Step S106]

The substrate having gone through PEB is developed, thereby producing a resist pattern.

Thereafter, an inspection and further subsequent processing steps are carried out.

### REFERENCE EXAMPLE 2

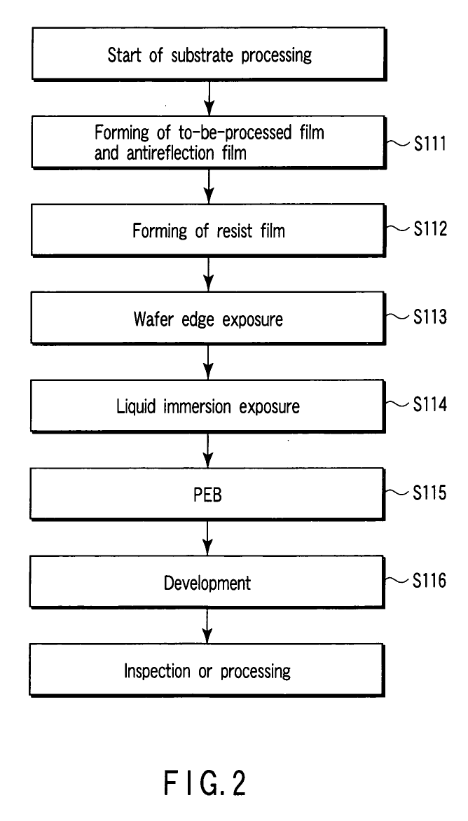

It is conceivable that wafer edge exposure is carried out in the same manner as dry exposure in immersion lithography. In this case, the sequence of steps is expected to be as described below because of the time between the pattern exposure and the PEB. Referring to FIG. 2, these steps will be explained. In reference example 2, no cover material film is provided on the resist film.

[Step S111, Step S112]

By the same steps as step S101 and S102, a to-be-processed film, an antireflection film, and a resist film are formed in sequence.

[Step S113]

By the same step as step S103, wafer edge exposure is carried out. When a commercially available coating and development tool and a commercially available exposure tool are used, wafer edge exposure is normally incorporated in the interface unit that transfers a wafer from the coating and development tool to the exposure tool like dry exposure. Therefore, wafer edge exposure is expected to be usually carried out immediately before exposure.

[Step S114]

The substrate having gone through wafer edge exposure is subjected to pattern exposure via a specific photomask using an immersion exposure tool, thereby causing photoreaction in the position corresponding to the pattern exposure of the resist film.

[Step S115]

By the same step as step S105, PEB is carried out.

[Step S116]

By the same step as step S106, developing is carried out.

When this example is carried out, however, a problem described below is expected to arise. Generally, in wafer edge exposure, the resist film is irradiated with light exposure one to two digits higher than in pattern exposure. Therefore, in the resist film having gone through wafer edge exposure, almost all PAG normally develops photoreactions and turns into photogenerated acid. The photogenerated acid produced by photoreactions at the exposed part is eluted more into the immersion fluid than the PAG at the unexposed part. For such a reason, there is a concern that a large amount of photogenerated acid (and PAG) is eluted into the immersion fluid during pattern exposure. As a result, problem 1 to problem 4 described in the background art become significant. As for the clouding of the optical system, the effect of PAG and photogenerated acid produced from PAG particularly becomes a big problem. Therefore, the development of a method of reducing the amount of material eluted from the resist film is wanted.

Such a problem is inevitable not only in a bath-type liquid immersion exposure tool which immerses all of a substrate in an immersion fluid (EP Pat. Appln. Publication No. 23231) but also in a showerhead-type liquid immersion exposure tool. This is because the showerhead has to scan the wafer edge exposure part of the substrate because of restrictions on the movement of the wafer stage. When the showerhead scans the wafer edge exposure part, more low-molecular components and photogenerated acid are particularly eluted from the resist film.

### REFERENCE EXAMPLE 3

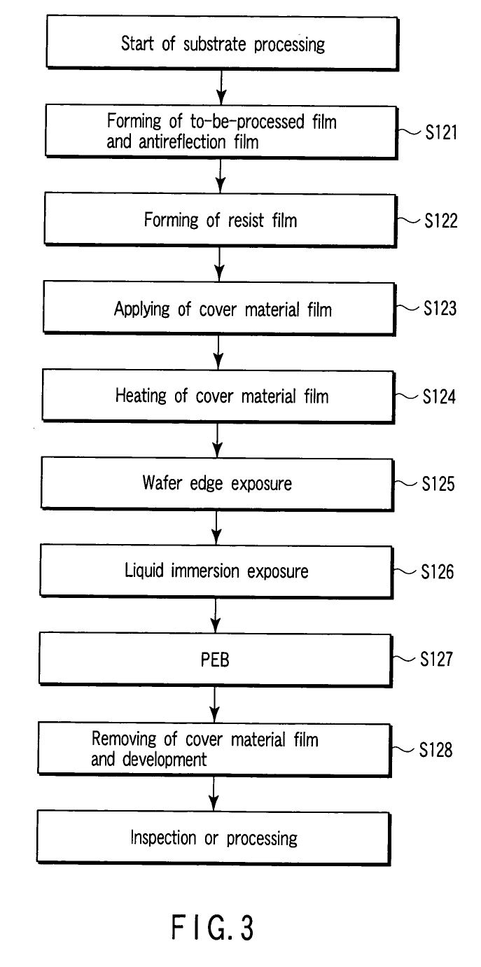

Reference example 3, like reference example 2, relates to the processing steps usually expected when a wafer edge exposure is inserted in the formation of a resist pattern with liquid immersion exposure. Such processing steps will be explained using FIG. 3. In reference example 3, a cover material film is provided on a resist film.

[Step S121, step S122]

By the same steps as step S101 and S102, a to-be-processed film, an antireflection film, and a resist film are formed in sequence.

[Step S123]

Dispensed cover material solution is spread by spin-coating on the substrate on which the resist film is formed, thereby forming a coating film of a cover material film.

[Step S124]

The substrate on which the coating film of a cover material film is formed is heated, thereby forming a cover material film. It is reported that the formation of the cover material film decreases the amount of material eluted into the immersion fluid by about one to two digits (K. Ishizuka, et al., “New Cover Material Development Status for Immersion Lithography, International Symposium on Immersion and 157-nm Lithography, Aug. 4, 2004).

[Step S125, step S127, step S127]

By the same steps as step S103, step S114, and step S105, wafer edge exposure, liquid immersion exposure, and PEB are carried out in sequence.

[Step S128]

The substrate having gone through PEB is subjected to the step of removing the cover material film with a specific agent. Then, as in step 116, developing is done.

Wafer edge exposure and liquid immersion exposure can sharpen the resist film at the periphery of the substrate as in reference example 1 and can form a more microscopic patterns than in dry exposure. Moreover, the formation of the cover material film can decrease material eluted into the immersion fluid.

However, even with the cover material film, the effect of suppressing material elution is insufficient. In addition, as described above, since in wafer edge exposure, the resist film is irradiated with light exposure higher than in pattern exposure, the resin structure of the cover material film can be photodegraded. As a result, the structure of the cover material film of the wafer edge exposure part changes, leading to the possibility that the amount of photogenerated acid eluted from the resist film into immersion fluid will increase. Moreover, gas caused by the photolytic degradation of the cover material film accumulated in the cover material film and/or at the interface between the cover material film and the resist film moves to the immersion fluid during pattern exposure, leading to the possibility that bubbles will be generated. As a result, the optical image of the resist pattern may change. When diffraction light in the immersion fluid passes the bubbles, it may deform the resist pattern.

Hereinafter, referring to the accompanying drawings, embodiments of the present invention configured on the basis of the above-described findings will be explained. In the explanation below, the component elements constituting almost the same function and configuration are indicated by the same reference numerals. A repeated explanation will be given only when necessary.

### FIRST EMBODIMENT

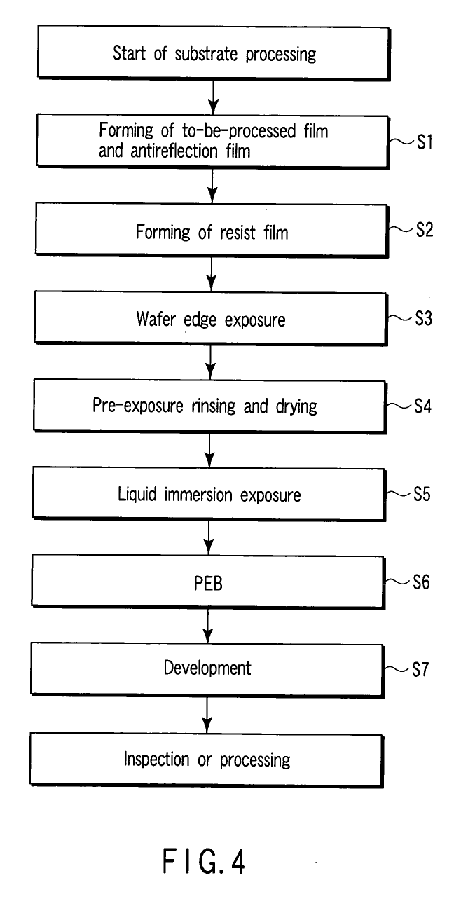

FIG. 4 is a flowchart to show a resist pattern forming method according to a first embodiment of the present invention. Referring to FIG. 4, the resist pattern forming method of the first embodiment will be explained.

[Step S1]

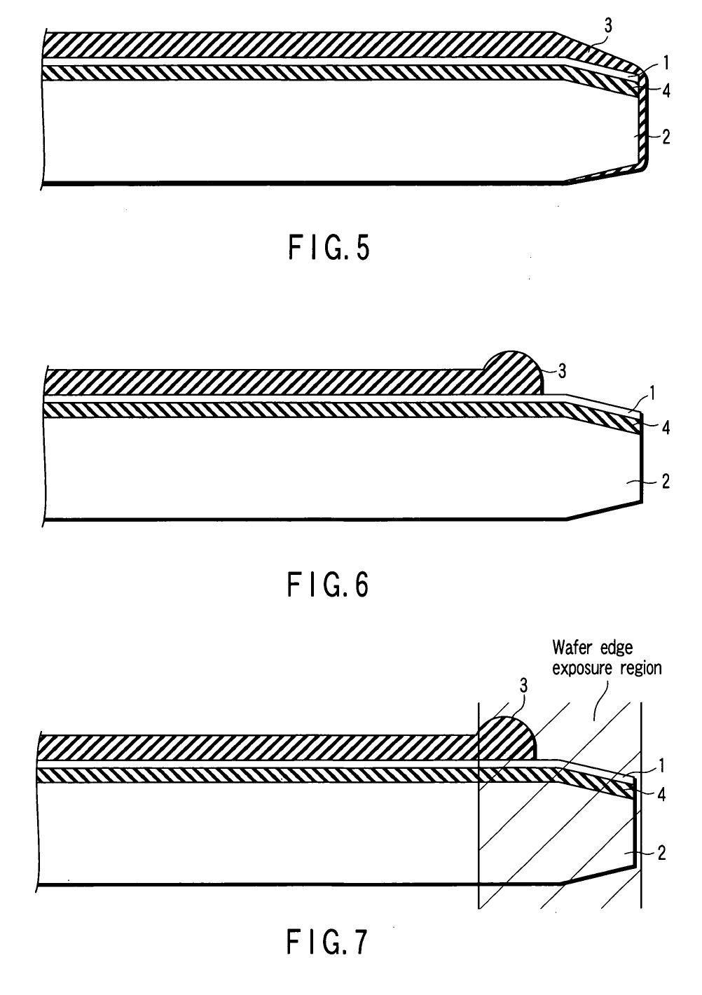

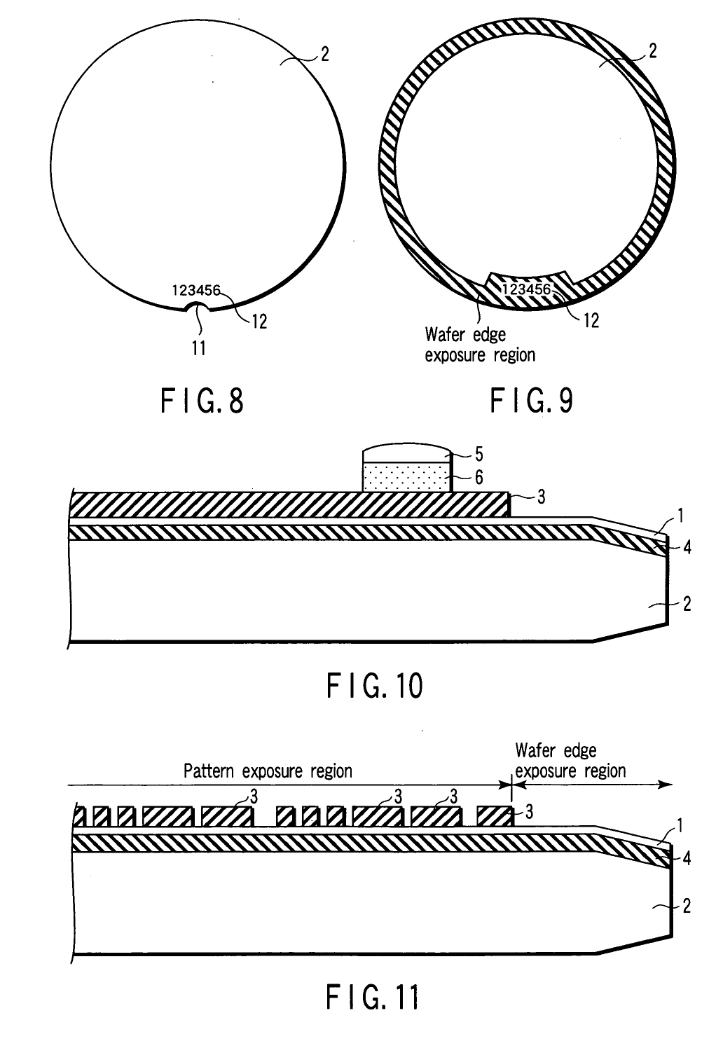

First, as shown in FIGS. 4 and 5, on a substrate 2, a to-be-processed film 4 and a single layer or more than one layers of antireflection films (bottom antireflection coating films (BARC films)) 1 are formed in sequence. The substrate 2 may be a semiconductor substrate itself or a semiconductor substrate on which insulating films, conductive films, and others have already been formed. Next, on the antireflection film 1, dispensed resist solution is spread by spin-coating, thereby forming a resist coating film 3.

In the manufacture of semiconductor elements, the application of resist is carried out by spin-coating. When a resist film is formed by spin-coating as shown in FIG. 5, the resist coating film 3 of the edge of the substrate 2 changes gently in thickness at the bevel part. At this time, depending on the amount of dispensed resist solution, the type of the solution, and the spin-coating sequence, the resist solution may go beyond the bevel part and reach the backside of the substrate 2, permitting the site to make contact with the transfer arm or wafer stage, which may cause dust or cross-contamination. Therefore, in the spin-coating, it is common practice to carry out back rinse. Back rinse involves applying chemical to dissolve the resist coating film 3 from the backside of the substrate 1.

When there is a part where the film thickness of the resist film decreases gently as shown in FIG. 5, or when there is uneven coating at the boundary of the resist coated region, irregularities occur in the processed film 4 below the site or in the surface of a further lower-layer film after the processing of the processed film 4 with the resist film as an etching mask. A lower-layer film in such a shape results in dust and/or contamination in the next and later steps. Moreover, irregularities in the edge of the substrate 1 cause abnormal coating or abnormal removing of a coated film, such as a resist film, giving rise to development defects. Therefore, normally, solution for back rinse is discharged over a specific area in the edge of the substrate 1 as in back rinse, thereby removing the resist solution at the bevel part (edge rinse). As a result, the resist coating film 3 after the spin-coating generally changes in thickness as shown in FIG. 6.

[Step S2]

By a specific process of heating the substrate on which the resist coating film 4 is formed, a resist film is formed.

[Step S3]

Wafer edge exposure is carried out. Wafer edge exposure involves irradiating a specific range of the edge of the substrate on which the resist film is formed with light whose intensity is almost uniform. The irradiated light in wafer edge exposure may be different in wavelength from the one in pattern exposure explained later or may be identical in wavelength to but different in intensity from the pattern exposure light.

Normally, wafer edge exposure is performed equally over a specific set distance from the edge of the substrate as shown in FIG. 7. However, when numbering 12 exists on the surface of the substrate, or when a notch 11 is formed in the substrate, wafer edge exposure may be carried out to an area beyond the set distance from the substrate.

Irradiated light in wafer edge exposure need not have the same wavelength as that of the irradiated light in pattern exposure and can have any wavelength to which the resist film is sufficiently photosensitive.

Performing wafer edge exposure causes the shape of the resist on the edge of the substrate to sharp change in film thickness as shown in FIG. 10, which prevents a problem in the processing step with the resist film as an etching mask. Therefore, in etching with the resist film as an etching mask, the problem of irregularities in the processed film can be reduced.

[Step S4]

The substrate having gone through wafer edge exposure is rinsed using, for example, pure water before exposure, followed by a drying. Photogenerated acid is eluted more into pure water than unexposed PAG. The rinsing reduces excessive photogenerated acid generated in the wafer edge exposure region. The rinsing also decreases the amount of PAG in the pattern exposure region. The decrease can be compensated by adjusting the light exposure in pattern exposure in accordance with the reduced amount. As described here, the pre-exposure rinsing can reduce the amount of eluted material generated from the resist film of the wafer edge exposure part during pattern exposure with an immersion exposure tool described later.

[Step 5]

The substrate rinsed and dried before exposure is subjected to pattern exposure via a specific photomask using the liquid-immersion exposure tool. Specifically, as shown in FIG. 10, exposure is performed in a state where the space between the last element 5 (typically, a lens) of the projection optical system and the substrate in the exposure region is filled with an immersion fluid 6 whose refractive index is larger than 1 (e.g., water (pure water)). The exposure causes photoreaction in the resist film in accordance with the pattern exposure. Liquid-immersion exposure may be carried out by a so-called bath-type method which involves immersing the entire substrate in an immersion fluid or a so-called showerhead type method which involves supplying an immersion fluid only in surrounding to the exposure part and scanning the immersion fluid supplier together with the lens.

Liquid-immersion exposure with a suitable designed optical system can form a more microscopic pattern than with dry exposure. Moreover, if patterns have the same period, the focal depth can be deeper in the embodiment.

[Step S6]

The substrate having gone through pattern exposure is subjected to a specific heating process (PEB) after exposure. PEB causes chemical reactions where photoreactions occurred in the resist film and its surroundings, thereby changing the solubility to the specific developer of the resist.

[Step S7]

The substrate having gone through PEB is developed using specific developer, thereby producing a resist pattern as shown in FIG. 11. In lithography where a substrate is irradiated with deep ultraviolet (DUV) light with a light source wavelength of, for example, 365 nm, 248 nm, 193 nm, 157 nm, a tetramthyl ammonium hydroxide (TMAH) developer, which is alkali solution, is usually used. Some of TMAH developers include various surfactants.

Next, the resist film is subjected to an inspection on its shape and an etching process of the processed film with the resist film as an etching mask is carried out. The steps described above and known semiconductor manufacturing steps, including ion implantation, are carried out, thereby forming a semiconductor device. This embodiment may be applied to not only semiconductor devices but also all devices manufactured using lithographic steps, such as magnetic elements, micro electro mechanical systems (MEMS), or DNA chips. This holds true for each of the embodiments described below.

In the resist pattern forming method according to the first embodiment, a pre-exposure rinsing and drying is carried out after wafer edge exposure. Therefore, liquid-immersion can form a microscopic pattern and wafer edge exposure can form a resist film with a sharp shape at its edge. Furthermore, the amount of material eluted from the wafer edge exposure part into the immersion fluid can be reduced remarkably. Consequently, a difference of optical length in the immersion fluid can be prevented and the stability of the exposure tool in long-term use can be assured.

Furthermore, in the first embodiment, PEB is carried out after pattern exposure. Therefore, the post exposure delay (PED) time is short. This can minimize the deterioration of the resolution of the resist film. In that sense, the first embodiment is effective when PED relatively greatly changes the resist material in the pattern dimensions or when the exposure process margin is very narrow.

A post-exposure rinsing and drying may be inserted between the liquid-immersion pattern exposure (step S5) and PEB (step S6).

Here, the pre-exposure rinsing and drying and post-exposure rinsing and drying do not necessarily mean that the rinsing solution in contact with the substrate in the rinsing dries completely and include a case where the substrate is dried to the extend that the rinse solution does not drip onto the back side of the substrate and in the tool. That is, when the rinse solution adsorbs to the surface, they include a case the chemical is included in the films on the substrate. This holds true for the embodiments described below.

### SECOND EMBODIMENT

A second embodiment of the present invention includes a cover material film added to the first embodiment.

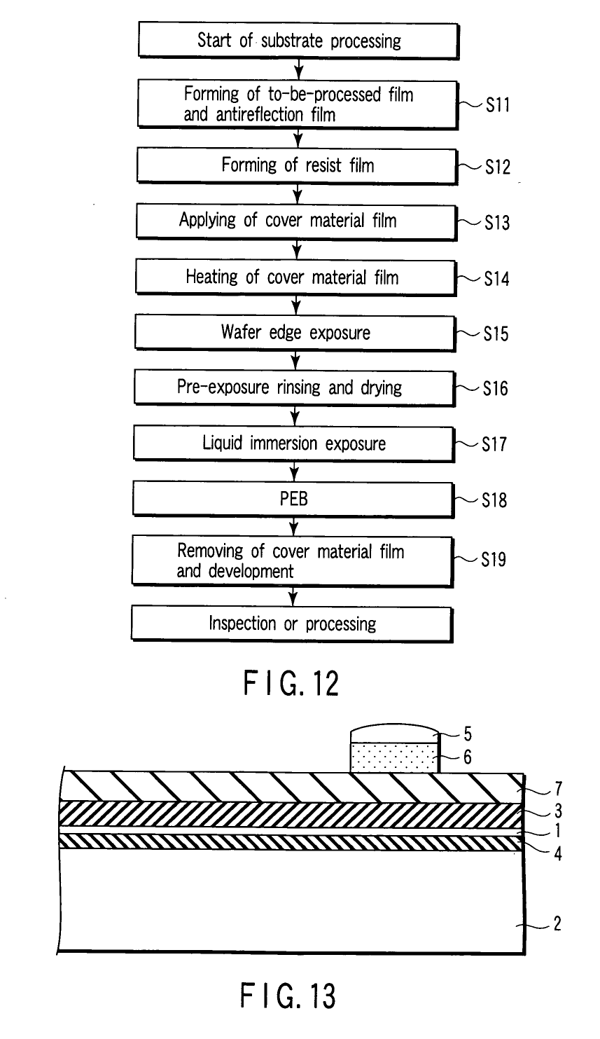

FIG. 12 is a flowchart of a resist pattern forming method according to the second embodiment. Referring to FIG. 12, the resist pattern forming method of the second embodiment will be explained.

[Step S11]

By the same step as step S1, a to-be-processed film, an antireflection film, and a resist coating film are formed in sequence. Edge rinse and back rinse are also carried out as in step S.

[Step S12]

The substrate on which the resist coating film is formed is subjected to the same step as step S2, thereby forming a resist film.

[Step S13]

Dispensed cover material solution is spread by spin-coating on the substrate on which the resist film is formed, thereby forming a coating film of a cover material film. The coating film of the cover material film is also subjected to edge rinse and back rinse.

It is desirable that the cover material film should cover all of the lower-layer films including at least the resist film or the antireflection film and material eluted into the immersion fluid. When the resist film and the film including material eluted into the immersion fluid exist on the side and lower layer of the bevel part of the substrate, it is desirable that back rinse (and edge rinse) should be set to allow the cover material film to cover a suitable range of the films because they may become dust source in the coating and developing tool and the exposure tool.

[Step S14]

The substrate on which the coating film of a cover material film is formed is subjected to a specific heating step, thereby forming a cover material film 7 as shown in FIG. 13. As described above, it is reported that the cover material film 7 decreases the amount of material eluted into the immersion fluid by about one or two digits.

[Step S15]

The substrate on which the cover material film 7 is formed is subjected to the same step as step S3, thereby carrying out wafer edge exposure.

[Step S16]

The substrate having gone through wafer edge exposure is subjected to the same step as step S4, thereby carrying out a pre-exposure rinsing and drying step.

[Step S17]

As shown in FIG. 13, the substrate having gone through the pre-exposure rinsing and drying is subjected to the same step as step S5, thereby making pattern exposure. The immersion fluid 6 is positioned between the cover material film 7 and the last element 5 of the projection optical system.

[Step S18]

The substrate having gone through pattern exposure is subjected to the same step as step S6, thereby carrying out PEB.

[Step S19]

A specific chemical is used for the substrate having gone through PEB to remove the cover material film.

Next, the substrate from which the cover material film is removed is subjected to the same step as step S7, thereby developing the substrate. When the cover material film dissolves into a developer, such as TMAM, the removing of the cover material film and development may be carried out consecutively and inseparably. Moreover, when the mixture of the solution for removing the cover material film and the developer causes no problem, removing and development may be carried out consecutively.

After developing is completed, the cover material film is removed completely.

In the resist pattern forming method of the second embodiment, the pre-exposure rinsing and drying is carried out after wafer edge exposure as in the first embodiment. Therefore, as in the first embodiment, it is possible not only to form a resist film which has a microscopic pattern and takes a sharp shape at its edge but also to reduce remarkably the amount of material eluted from the wafer edge exposure part into the immersion fluid.

Furthermore, in the second embodiment, the cover material film is formed. This can reduce the amount of material eluted into the immersion fluid more than in the first embodiment. On the other hand, when wafer edge exposure decomposes the cover material film resin, gas derived from the cover material film or lowered ability of suppressing material eluted from the cover material film as a result of the decomposition may lead higher amount of material eluted from the resist film than the area having gone through no wafer edge exposure. However, in the second embodiment where the pre-exposure rinsing and drying is carried out after the cover material film is formed and wafer edge exposure is made, the amount of photogenerated acid and the like eluted from the wafer edge exposure part of the resist film can be suppressed. Moreover, removal of the cover material film-derived gas accumulated in the cover material film and/or at the interface between the cover material film and the resist film and gas such as cation of PAG can prevent the generation of bubbles in this area and can avoid long-term instability due to an increase in the amount of eluted material. As a result, it is possible to avoid a change in the optical image of the resist pattern.

In addition, the PED time is short in the second embodiment as in the first embodiment. Therefore, the deterioration of the resolution of the resist film can be minimized.

A rinsing and drying may be inserted between pattern exposure with immersion exposure tool and PEB as in the first embodiment.

### THIRD EMBODIMENT

A third embodiment of the present invention differs from the second embodiment in step sequence.

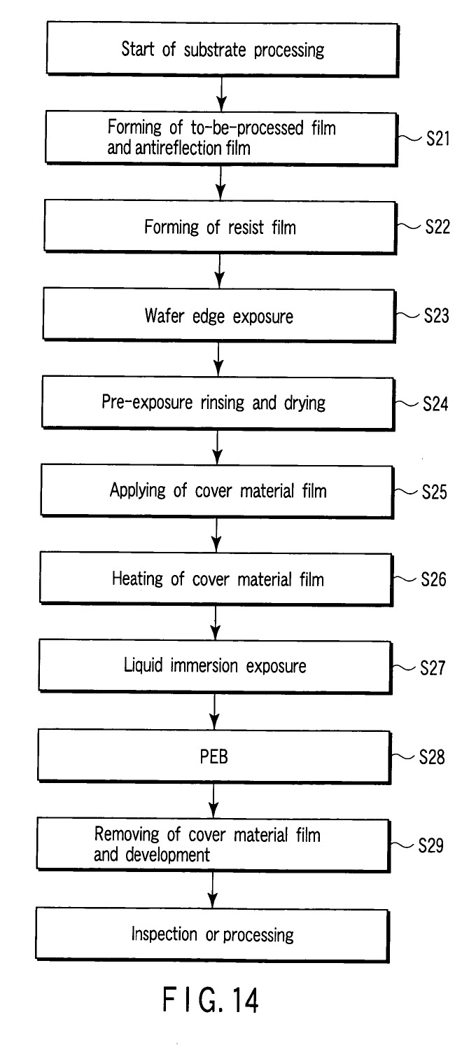

FIG. 14 is a flowchart of a resist pattern forming method according to the third embodiment. Referring to FIG. 14, the resist pattern forming method of the third embodiment will be explained.

[Step S21]

The same step as step S1 is carried out, thereby forming a to-be-processed film, an antireflection film, and a resist coating film. Edge rinse and back rinse are also carried out as in step S1.

[Step S22]

The substrate on which the resist coating film is formed is subjected to the same step as step S2, thereby forming a resist film.

[Step S23]

A specific range of the edge of the substrate on which the resist film is formed is subjected to the same step as step S3, thereby carrying out wafer edge exposure.

[Step S24]

The substrate having gone through wafer edge exposure is subjected to the same step as step S4, thereby carrying out a pre-exposure rinsing and drying.

[Step S25]

The substrate subjected having gone through the pre-exposure rinsing and drying is subjected to the same step as step S13, thereby forming a coating film of the cover material film.

[Step S26]

The substrate on which the coating film of the cover material film is formed is subjected to the same step as step S14, thereby forming a cover material film.

[Step S27]

The substrate on which the cover material film is formed is subjected to the same step as step S5, thereby carrying out pattern exposure.

[Step S28]

The substrate having gone through pattern exposure is subjected to the same step as step S6, thereby carrying out PEB.

[Step S29]

The substrate having gone through PEB is subjected to the same step as step S19, thereby removing the cover material film and developing the substrate.

In the resist pattern forming method of the third embodiment, the pre-exposure rinsing and drying is carried out after wafer edge exposure as in the first embodiment. Therefore, as in the first embodiment, it is possible not only to form a resist film which has a microscopic pattern and takes a sharp shape at its edge but also to remarkably reduce the amount of material eluted from the wafer edge exposure part into the immersion fluid.

The cover material film is formed in the third embodiment as in the second embodiment. Thus, it is possible to reduce the amount of material eluted into the immersion fluid as in the second embodiment.

The cover material film is formed after wafer edge exposure in the third embodiment. Therefore, it is possible to prevent wafer edge exposure from changing the structure of the cover material film. Accordingly, the amount of photogenerated acid and the like eluted from the wafer edge exposure part of the resist film can be suppressed. As a result, it is possible to avoid a change in the optical image of the resist pattern.

The PED time is short in the third embodiment as in the first embodiment. Therefore, the deterioration of the resolution of the resist film can be minimized.

A rinsing-and-drying may be inserted between pattern exposure with immersion exposure tool and PEB as in the first embodiment.

### FOURTH EMBODIMENT

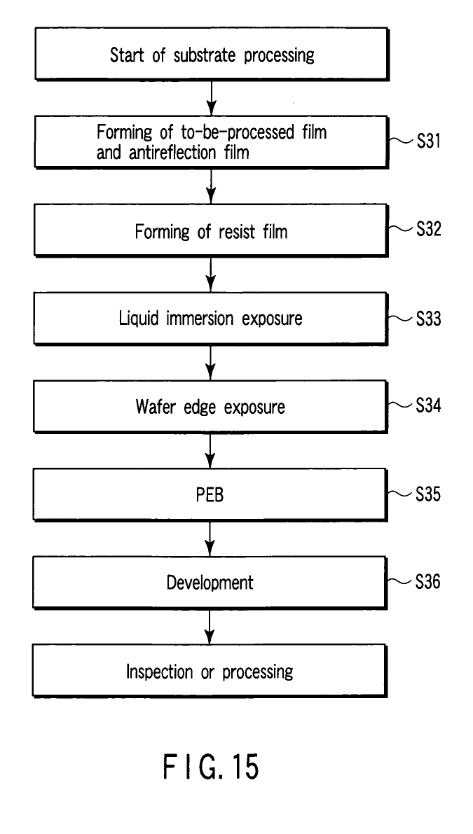

FIG. 15 is a flowchart of a resist pattern forming method according to a fourth embodiment of the present invention. Referring to FIG. 15, the resist pattern forming method of the fourth embodiment will be explained.

[Step S31]

The same step as step S1 is carried out, thereby forming a to-be-processed film, an antireflection film, and a resist coating film. Edge rinse and back rinse are also carried out as in step S1.

[Step S32]

The substrate on which the resist coating film is formed is subjected to the same step as step S2, thereby forming a resist film.

[Step S33]

The substrate on which the resist film is formed is subjected to the same step as step S5, thereby making pattern exposure.

[Step S34]

The substrate having gone through pattern exposure is subjected to the same step as step S3, thereby making wafer edge exposure.

[Step S35]

The substrate having gone through wafer edge exposure is subjected to the same step as step S6, thereby carrying out PEB.

[Step S36]

The substrate having gone through PEB is subjected to the same step as step S7, thereby developing the substrate.

In the resist pattern forming method of the fourth embodiment, wafer edge exposure is carried out after pattern exposure. Therefore, at the time of liquid immersion exposure, the edge of the resist film has not been irradiated yet. As a result, it is possible to form a resist film which has a microscopic pattern produced by liquid immersion and takes a sharp shape at its edge as a result of wafer edge exposure and remarkably reduce the amount of material eluted from the wafer edge exposure part into the immersion fluid. Consequently, the occurrence of a difference of optical length in the immersion fluid can be prevented and the stability of the exposure tool in long-term use can be assured.

Unlike the first to fourth embodiments, the fourth embodiment does not require any step (such as a pre-exposure rinsing and drying) to be added to the conventional steps. Therefore, it is not necessary to make a significant change to the arrangement of the units for carrying out the steps in the above sequence and the control program in the coating and developing tool, the exposure tool, or the interface unit between them.

The main reason why wafer edge exposure is carried out before pattern exposure in reference examples 1 and 2 is concern about a change in the pattern dimensions and the deterioration of resolution due to PED. However, time lapse causes only small variation of the dimensions among wafers because the time required for wafer edge exposure is about 30 seconds and controlling the substrate transfer time from the exposure tool to the PEB unit via the wafer edge exposure tool by software can also suppress the variation.

As in the first embodiment, a rinsing and drying may be inserted between pattern exposure with immersion exposure tool and the PEB, that is, before wafer edge exposure (step S34). When the existing unit is used, the step is likely to be inserted after wafer edge exposure.

A post-exposure rinsing may be inserted between the resist film formation (step S32) and pattern exposure (step S33) as described in A. K. Paub, et al., “Proc. SPIE,” vol. 5377, 2004, pp. 306-318. This can reduce the amount of material eluted from the pattern exposure region during pattern exposure by liquid immersion exposure.

### FIFTH EMBODIMENT

A fifth embodiment of the present invention includes a cover material film added to the fourth embodiment.

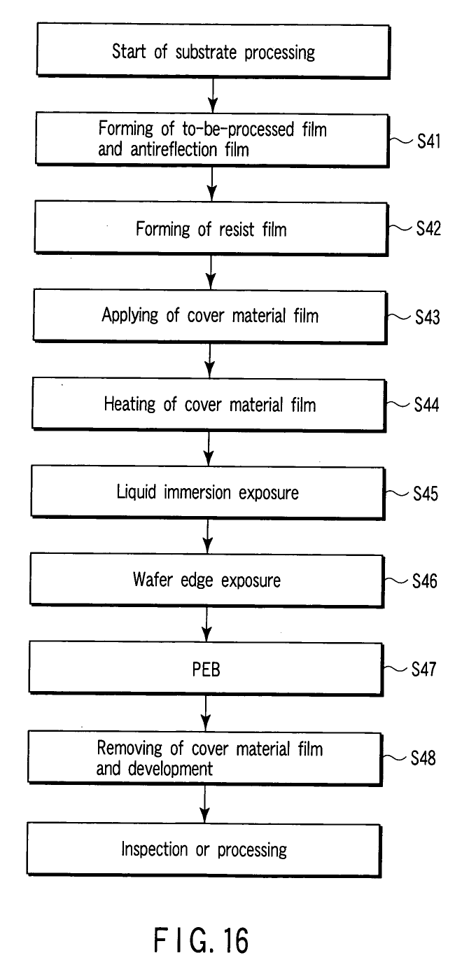

FIG. 16 is a flowchart to show a resist pattern forming method of the fifth embodiment. Referring to FIG. 16, the resist pattern forming method of the fifth embodiment will be explained.

[Step S41]

First, the same step as step S1 is carried out, thereby forming a to-be-processed film, an antireflection film, and a resist coating film. Edge rinse and back rinse are also carried out as in step S1.

[Step S42]

The substrate on which the resist coating film is formed is subjected to the same step as step S2, thereby forming a resist film.

[Step S43]

The substrate on which the resist film is formed is subjected to the same step as step S13, thereby forming a coating film of the cover material film.

[Step S44]

The substrate on which the coating film of the cover material film is formed is subjected to the same step as step S14, thereby forming a cover material film.

[Step S45]

The substrate on which the cover material film is formed is subjected to the same step as step S5, thereby making pattern exposure.

[Step S46]

The substrate having gone through pattern exposure is subjected to the same step as step S3, thereby making wafer edge exposure.

[Step S47]

The substrate having gone through wafer edge exposure is subjected to the same step as step S6, thereby carrying out PEB.

[Step S48]

The substrate subjected having gone through PEB is subjected to the same step as step S19, thereby removing the cover material film and then developing the substrate.

In the resist pattern forming method of the fifth embodiment, wafer edge exposure is carried out after pattern exposure as in the fourth embodiment. Therefore, the fifth embodiment produces the same effect as that of the fourth embodiment.

A cover material film is formed in the fifth embodiment as in the second embodiment. Therefore, the amount of material eluted into the immersion fluid is low as in the second embodiment.

A rinsing and drying may be inserted between pattern exposure with immersion exposure tool and PEB as in the first embodiment. When the existing unit is used, the step is likely to be inserted after wafer edge exposure as in the fourth embodiment.

In addition, a pre-exposure rinsing may be inserted between the resist film formation and pattern exposure as in the fourth embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A resist pattern forming method comprising:
forming a resist film above a substrate;
performing a first exposure in which a specific region of an edge of the resist film is irradiated with light much enough to allow subsequent development to dissolve the resist film, thereby forming a latent image in the resist film at the edge;
rinsing the resist film whose edge has been irradiated;
performing a second exposure in which a desired pattern of light is projected onto an exposure region of the rinsed resist film via a projection optical system of an immersion exposure tool whose refractive index is larger than that of air existing between the exposure region and the substrate-side face of a component element closest to the substrate in the projection optical system; and
performing development on the exposure region of the resist film.

2. The method according to claim 1, further comprising heating the resist film after the second exposure and before the development.

3. The method according to claim 1, further comprising:
forming a first film on the resist film before the second exposure; and
removing the first film after the second exposure and before the development.

4. The method according to claim 3, wherein the first film is formed after forming the resist film and
the first exposure is performed after forming the first film.

5. The method according to claim 3, wherein the first film is formed after rinsing the resist film and
the second exposure is performed after forming the first film.

6. The method according to claim 3, further comprising heating the resist film after the second exposure and before the development.

7. The method according to claim 6, wherein the first film is formed after forming the resist film and
the first exposure is performed after forming the first film.

8. The method according to claim 6, wherein the first film is formed after rinsing the resist film and
the second exposure is performed after forming the first film.

9. The method according to claim 6, wherein the resist film is heated after the second exposure and
the first film is removed after the resist film is heated.

10. The method according to claim 9, wherein the first film is removed and the development is performed in a same processing unit.

11. A resist pattern forming method comprising:
forming a resist film above a substrate;
performing a first exposure in which a desired pattern of light is projected onto a exposure region of the resist film via a projection optical system of an immersion exposure tool with liquid whose refractive index is larger than that of air existing between the exposure region and the substrate-side face of a component element closest to the substrate in the projection optical system;
after the first exposure, performing a second exposure in which a specific region of an edge of the resist film is irradiated with light much enough to allow subsequent development to dissolve the resist film, thereby forming a latent image in the resist film at the edge; and
performing development on the exposure region of the resist film.

12. The method according to claim 11, further comprising heating the resist film after the first exposure and before the development.

13. The method according to claim 12, wherein the resist film is heated after the second exposure.

14. The method according to claim 11, further comprising:
forming a first film on the resist film after forming the resist film and before the first exposure; and
removing the first film after the first exposure and the development.

15. The method according to claim 14, wherein the resist film is heated after the first exposure and before the development.

16. The method according to claim 15, wherein the resist film is heated after the second exposure and
the first film is removed after the resist film is heated.

17. The method according to claim 16, wherein the first film is removed and the development is performed in a same processing unit.

18. A semiconductor device manufacturing method comprising:
forming a to-be-processed film on a substrate;
forming a resist pattern on the to-be-processed film by a resist pattern forming method as defined in claim 1; and
processing the to-be-processed film using the resist pattern as a mask material.

19. A semiconductor device manufacturing method comprising:
forming a to-be-processed film on a substrate;
forming a resist pattern on the to-be-processed film by a resist pattern forming method as defined in claim 3; and
processing the to-be-processed film using the resist pattern as a mask material.

20. A semiconductor device manufacturing method comprising:
forming a to-be-processed film on a substrate;
forming a resist pattern on the to-be-processed film by a resist pattern forming method as defined in claim 11; and
processing the to-be-processed film using the resist pattern as a mask material.
